(19) United States
(12) Patent Application Publication
(10) Pub. No.: US 2026/0103799 A1
(43) Pub. Date: Apr. 16, 2026

(54) METHODS AND SYSTEM FOR PRECURSOR RECYCLING

(71) Applicant: ASM IP Holding B.V., Almere (NL)

(72) Inventors: Paul Ma, Scottsdale, AZ (US); Jacqueline Wrench, Mesa, AZ (US)

(21) Appl. No.: 19/032,149

(22) Filed: Jan. 20, 2025

Related U.S. Application Data
(60) Provisional application No. 63/623,940, filed on Jan. 23, 2024.

(51) Int. Cl. C23C 16/448; C23C 16/455; C23C 16/52

(52) U.S. Cl. CPC C23C 16/4487; C23C 16/45544; C23C 16/52

(57) ABSTRACT

Various embodiments of the present technology may provide a reactor, a first vessel having an inlet coupled to an inlet of the reactor, a second vessel having an inlet coupled to the inlet of the reactor, and an exhaust line coupled to an outlet of the reactor, the inlet of the first vessel, and the inlet of the second vessel. The first and second vessels may be configured to receive a vapor though the exhaust line and recondense the vapor into a solid material to be reused during a precursor pulsing step.

### CROSS-REFERENCE TO RELATED APPLICATIONS

This application is a nonprovisional of, and claims priority to and the benefit of, U.S. Provisional Patent Application No. 63/623,940, filed Jan. 23, 2024 and entitled “METHODS AND SYSTEM FOR PRECURSOR RECYCLING,” which is hereby incorporated by reference herein.

### FIELD OF INVENTION

The present disclosure generally relates to a method and system for semiconductor equipment. More particularly, the present disclosure relates to a method and system for precursor recycling.

### BACKGROUND OF THE TECHNOLOGY

During a typical ALD process, precursor is pulsed and purged over a number of cycles to deposit a thin film on a substrate, such as a wafer. During the purging step, any remaining precursor that has not reacted with the surface of the substrate will be purged out with an inert gas and removed via an exhaust system. In conventional systems, during the purging step, the remaining precursor is not reused, but rather is dispersed into the atmosphere.

### SUMMARY OF THE INVENTION

Various embodiments of the present technology may provide a reactor, a first vessel having an inlet coupled to an inlet of the reactor, a second vessel having an inlet coupled to the inlet of the reactor, and an exhaust line coupled to an outlet of the reactor, the inlet of the first vessel, and the inlet of the second vessel. The first and second vessels may be configured to receive a vapor though the exhaust line and recondense the vapor into a solid material to be reused during a precursor pulsing step.

According to one aspect, a system comprises: a reactor comprising an inlet and an outlet; a first vessel comprising a first inlet and a first outlet coupled to the inlet of the reactor; a second vessel comprising a second inlet and a second outlet coupled to the inlet of the reactor; and an exhaust line coupled to the outlet of the reactor, the first inlet of the first vessel, and the second inlet of the second vessel; wherein the first and second vessels are configured to receive a vapor though the exhaust line and recondense the vapor into a solid material.

### BRIEF DESCRIPTION OF THE DRAWING FIGURES

A more complete understanding of the present technology may be derived by referring to the detailed description when considered in connection with the following illustrative figures. In the following figures, like reference numbers refer to similar elements and steps throughout the figures.

FIG. 1 representatively illustrates a system in accordance with embodiments of the present technology; and

FIG. 2 is a method for operating the system in accordance with embodiments of the present technology.

### DETAILED DESCRIPTION OF EXEMPLARY EMBODIMENTS

The present technology may be described in terms of functional block components and various processing steps. Such functional blocks may be realized by any number of components configured to perform the specified functions and achieve the various results. For example, the present technology may employ various vessels, reaction chambers, piping, pumps, valves, and heating elements.

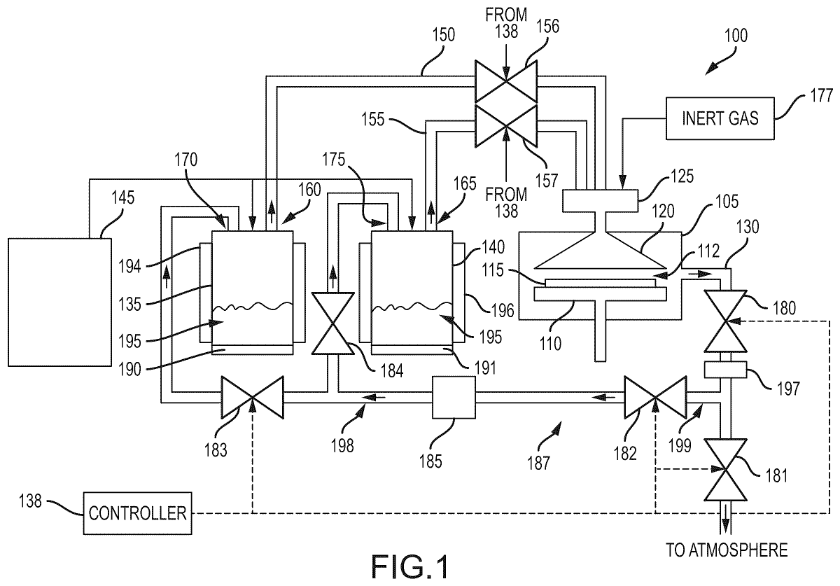

Referring to FIG. 1, an exemplary system 100 may comprise a first vessel 135, a second vessel 140, and a reactor 105. In an exemplary embodiment, the reactor 105 may be configured for processing a substrate, such as a wafer 115. The reactor 105 may comprise a susceptor 110 to support the wafer, a reaction space 112 and a showerhead 120, positioned above the reaction space 112 and the susceptor 110, and configured to deliver chemistry to the reaction space 112 and the wafer 115.

The system 100 may further comprise an exhaust system that may be partially integrated in the reactor 105 and/or disposed outside of the reaction chamber 105. In various embodiments, the system 100 may be configured to recycle precursor from the reactor 105 to be reused during a processing step.

In an exemplary embodiment, the reactor 105 may comprise an inlet 125 and an exhaust outlet 130. The first vessel 135 may be coupled to the inlet 125. For example, an outlet 160 of the first vessel 135 may be coupled to the inlet 125 via a first conduit 150. In addition, the second vessel 140 may be coupled to the inlet 125. For example, an outlet 165 of the second vessel 140 may be coupled to the inlet 125 via a second conduit 155. The first and second conduits 150, 155 may be configured to allow the flow of a vapor from the respective vessel 135, 140 to the inlet 125 of the reactor 105. In addition, the first and second conduits 150, 155 may be actively heated to a temperature that prevents the vapor from the first and second vessels 135, 140 from recondensing inside the first and second conduits 150, 155. For example, the second conduit 135 may be heated by any suitable heating elements, such as heater jackets, printed heaters, convection heating, and the like.

In an exemplary embodiment, the exhaust outlet 130 may be coupled to an inlet 170 of the first vessel 135 and an inlet 175 of the second vessel 140. The exhaust outlet 130 may also be in communication with the atmosphere.

In various embodiments, the exhaust system may further comprise a pump 197 configured to facilitate pumping vapor or gas out of the reactor 105. The pump 197 may comprise any device or system suitable for facilitating flow of a vapor. In addition, the exhaust system may comprise a plurality of valves, such as a first valve 180 and a second valve 181. The first valve 180 may be disposed downstream from the exhaust outlet 130, and the pump 197 may be disposed downstream from the first valve 180. The second valve 181 may be disposed downstream from the pump 197.

In various embodiments, the exhaust system may further comprise a return conduit 199. The return conduit 199 may be coupled between the pump 197 and the second valve 181. The return conduit 199 may couple the exhaust outlet 130 to the inlets of the first and second vessels 135, 140.

In an exemplary embodiment, the first vessel 135 may be configured to contain or otherwise hold a solid material 195 (e.g., a solid precursor chemical). In various embodiments, the solid precursor may be in the form of a powder. The solid precursor may comprise a Group 2, 13, 14, or 15 element and transition metal halides or a Group 2, 13, 14, or 15 element and transition metal metallorganics that are solid at room temperature (e.g., 20-25 degrees Celsius) and with a melting point above 50 degrees Celsius. In an exemplary embodiment, the solid precursor comprises a molybdenum compound, such as a solid molybdenum halide (e.g., MoCl₂ or MoOCl₄).

In the present embodiment, the first vessel 135 may be formed from a metal material, such as stainless steel, Hastelloy, aluminum, or the like.

The first vessel 135 may be configured to be maintained at a first temperature, for example, approximately 20-25 degrees Celsius, such that the solid material 195 is also maintained at the first temperature. In addition, the first vessel 135 may be configured to sublimate the solid material 195. For example, the first vessel 135 may comprise a heating device 194 configured to heat the first vessel 135 and the solid material 195 to a temperature at which the solid material 195 sublimates and transforms into a vapor. The heating device 194 may comprise any suitable heating system or method, such as a heater jacket or a heating apparatus with heating rods embedded within the heating apparatus, in direct contact with an exterior surface of the first vessel 135. Alternatively, the heating device 194 may provide indirect heat to the first vessel 135, for example by convection heating. In some embodiments, the first vessel 135 may comprise a sublimator.

In various embodiments, the first vessel 135 may further comprise a cooling device 190 configured to cool the first vessel 135 to the first temperature from higher temperature (e.g., greater than 25 degrees Celsius). The cooling device 190 may be in direct contact with an outer surface of the first vessel 135 and may comprise any suitable cooling system or method, such as a cooling coil with cooling fluid flowing through the coil, cooling gas flowing through a coil, a thermoelectric module configured for cooling the first vessel 135, or the like.

Similarly, in various embodiments, the second vessel 140 may be configured to contain or otherwise hold a solid material 195 (e.g., a solid precursor chemical). In various embodiments, the solid precursor may be in the form of a powder. The solid precursor may comprise a Group 2, 13, 14, or 15 element and transition metal halides or a Group 2, 13, 14, or 15 element and transition metal metallorganics that are solid at room temperature (e.g., 20-25 degrees Celsius) and with a melting point above 50 degrees Celsius. In an exemplary embodiment, the solid precursor comprises a molybdenum compound, such as a solid molybdenum halide (e.g., MoCl₂ or MoOCl₄).

In the present embodiment, the second vessel 140 may be formed from a metal material, such as stainless steel, Hastelloy, aluminum, or the like.

The second vessel 140 may be configured to be maintained at the first temperature, for example, approximately 20-25 degrees Celsius, such that the solid material 195 is also maintained at the first temperature. In addition, the second vessel 140 may be configured to sublimate the solid material 195. For example, the second vessel 140 may comprise a heating device 196 configured to heat the second vessel 140 and the solid material 195 to a temperature at which the solid material 195 sublimates and transforms into a vapor. The heating device 196 may comprise any suitable heating system or method, such as a heater jacket or a heating apparatus with heating rods embedded within the heating apparatus, in directly contact with an exterior surface of the first vessel 135. Alternatively, the heating device 196 to provide indirect heat to the second vessel 140, for example by convection heating. In some embodiments, the second vessel 140 may comprise a sublimator.

In various embodiments, the second vessel 140 may further comprise a cooling device 191 configured to cool the second vessel 140 to the first temperature from higher temperature (e.g., greater than 25 degrees Celsius). The cooling device 191 may comprise any suitable cooling system or method, such as a cooling coil, in direct contact with an outer surface of the vessel 140, with cooling fluid flowing through the coil, cooling gas flowing through a coil, a thermoelectric module configured for cooling the second vessel 140, or the like.

In various embodiments, the system 100 may further comprise a plurality of valves, such as a first valve 180, a second valve 181, a third valve 182, a fourth valve 183, and a fifth valve 184. In particular, the plurality of valves may be disposed along the exhaust system flow path. For example, the first valve 180 may be disposed downstream from the exhaust outlet 130, the second valve 181 may be disposed downstream from the first valve 180. In an exemplary embodiment, the pump 197 may be disposed between the first valve 180 and the second valve 181.

In various embodiments, the system 100 may further comprise additional valves, such as a sixth valve 156 disposed along the first conduit 150, and a seventh valve 157 disposed along the second conduit 155. The sixth and seventh valves 156, 157 may be operated to pulse the vapor from the respective vessel into the reactor 105.

In an exemplary embodiment, the exhaust system may comprise a feedback portion 187 that is fluidly coupled to the exhaust outlet 130. For example, the feedback portion may be connected between the pump 197 and the second valve 181 at a junction 199.

In an exemplary embodiments, the feedback portion 187 may comprise the second and third valves 182, 183. In addition, the feedback portion 187 may further comprise a filter 185. The filter 185 may be configured to remove or otherwise neutralize contaminants in the exhaust vapor. For example, the filter 185 may comprise a porous filter, or any other filter suitable for capturing particles or contaminants in a vapor. The filter may be disposed upstream from the fourth and fifth valves 183, 184, and downstream from the third valve 182.

In various embodiments, the feedback portion 187 of the exhaust system may connect to the first and second vessels 135, 140. For example, the feedback portion 187 may be coupled to the inlet 170 of the first vessel 135 and the inlet 175 of the second vessel 140. The feedback portion 187 may comprise a junction 198, such as a T-junction, with one leg coupled to the inlet 170 of the first vessel 135 and a second leg coupled to the inlet 175 of the second vessel 140. Fourth valve 183 can be coupled to one leg (to regulate flow to inlet 170 of first vessel 135), and fifth valve 184 can be coupled to the second leg (to regulate flow to inlet 175 of second vessel 140). The filter 185 may be disposed upstream from the junction 198.

In various embodiments, the system 100 may further comprise a third vessel 145 configured to hold or otherwise contain a chemical, such as the same chemical in the first and second vessels 135, 140. The third vessel 145 may be coupled to a second inlet of the first vessel 135 and a second inlet of the second vessel 140. The third vessel 145 may be used to refill the first and second vessels 135, 140 with a desired chemistry when the first and second vessels 135, 140 are nearly or completely depleted of the desired chemical.

In various embodiments, the first and second vessels 135, 140 and the reactor 105 may be located within a processing area, such that first and second vessels 135, 140 and the reactor 105 are all physically located near each other or enclosed within a particular tool or area (i.e., cleanroom, semiconductor fabrication area). The third vessel 145, however, may be located in a non-processing area that is remotely-located from the processing area, such as an area physically below the processing area (i.e., a sub-fab).

In various embodiments, the system 100 may further comprise a controller 138 configured to generate and transmit various control signals. For example, the controller 138 may be communicatively coupled to the plurality of valves (e.g., valves 156, 157, 180, 181, 182, 183) and transmit a control signal to each valve. The control signal may indicate an operation or state of the respective valve (e.g., open or closed). The controller 138 may also control the operation of the heating devices 194, 196 and cooling devices 190, 191. The heating devices 194, 196 may be controlled independently from each other. Similarly, the cooling devices 190, 191 may be controlled independently from each other.

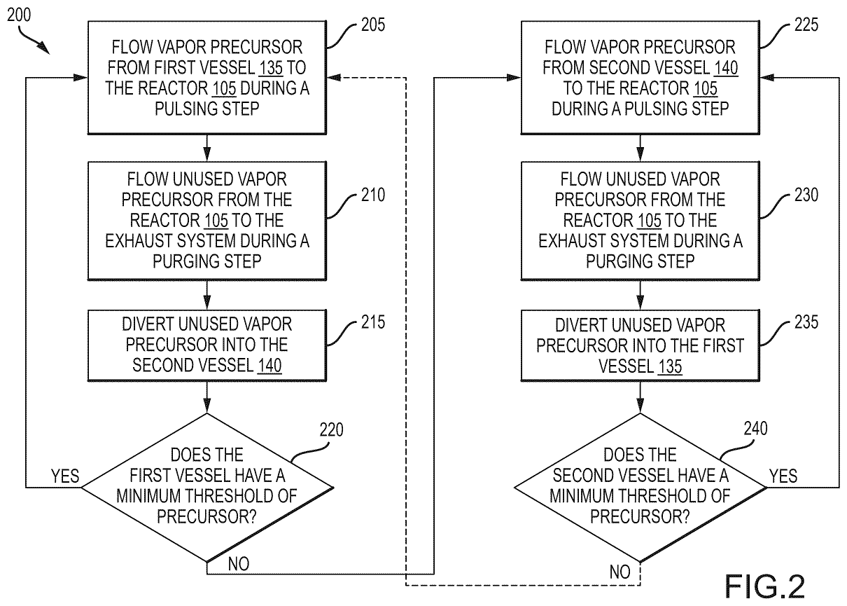

In operation, and referring to FIGS. 1 and 2, during processing 200, precursor from the first vessel 135 may be pulsed (during a pulsing step) into the reactor 105 (205). In an exemplary embodiment, only one vessel is used for processing, while the other vessel is in an idle state and not processing. During the idle state, the vessel is not at a processing temperature or sublimating the precursor. For example, the idle vessel is at a room temperature or any other temperature that allows the precursor to remain in a solid state. During the pulsing step (205), the controller 138 may operate the fifth valve 156 to flow vapor from the first vessel 135 into the reactor 105. After the pulsing step, the unused precursor may be purged (during a purging step) from the reaction space 112 (210). During the purging step (215), an inert gas 177 may be flowed through the showerhead 120 and into the reaction space 112, and as the inert gas 177 is flowed, the unused precursor may be flowed out of the reactor 105 and into the exhaust system along with the inert gas. For example, the pump 197 may be activated and the first valve 180 may be opened. In cases where the unused precursor is recycled, the second valve 181 is closed and the unused precursor is flowed into the feedback portion 187 of the exhaust system. Since the first vessel 135 is currently being used for processing, the unused precursor is flowed into the second vessel 140. For example, the pump 197 may be ON, and the controller 138 may open the first valve 180, close the second valve 181, open the third valve 182, close the fourth valve 183, and open the fifth valve 184. The second vessel 140 is set at a temperature that allows the vapor precursor to recondense into a solid state. The system 100, such as the controller 138 and other sensors, such as a level sensor (not shown), may monitor the level of precursor 195 in the first vessel 135 (220). As long as the precursor in the first vessel 135 does not drop below a predetermined minimum threshold, the system 100 will continue to use precursor from the first vessel 135 for processing. Once the precursor in the first vessel 135 drops below the minimum threshold, the system 100 will utilize the precursor in the second vessel 140 for processing (225). During the purging step (230), the inert gas 177 may be flowed through the showerhead 120 and into the reaction space 112, and the unused precursor is flowed through the exhaust system and diverted into the first vessel 135, which is now at a temperature that is less than the processing temperature and one that allows the vapor precursor to recondense in the first vessel 135. For example, the pump 197 may be ON, and the controller 138 may open the first valve 180, close the second valve, open the third valve 182, open the fourth valve 183, and close the fifth valve 184.

The system 100, such as the controller 138 and other sensors (not shown), may monitor the level of precursor in the second vessel 140 (240). As long as the precursor in the second vessel 140 does not drop below a predetermined minimum threshold, the system 100 will continue to use precursor from the second vessel 140 for processing. Once the precursor in the second vessel 140 drops below the minimum threshold, the system 100 will utilize the precursor in the first vessel 135 for processing (205).

The steps described above may continue in a cyclical manner. In addition, during processing, the vessel being used to receive the recycled precursor vapor may also be refilled with chemistry from the third vessel 145.

As the precursor exhaust flows through the filter 185 to the first or second vessels 135, 140, the filter 185 may remove or neutralize contaminants, such as water, organic materials, and the like.

In some cases, where precursor recycling is not desired, the exhaust system may facilitate flow of the exhaust vapor to the atmosphere. For example, the pump 197 is ON, the first and second valves 180, 181 are open and the third valve is closed 182.

In the foregoing description, the technology has been described with reference to specific exemplary embodiments. The particular implementations shown and described are illustrative of the technology and its best mode and are not intended to otherwise limit the scope of the present technology in any way. Indeed, for the sake of brevity, conventional manufacturing, connection, preparation, and other functional aspects of the method and system may not be described in detail. Furthermore, the connecting lines shown in the various figures are intended to represent exemplary functional relationships and/or steps between the various elements. Many alternative or additional functional relationships or physical connections may be present in a practical system.

The technology has been described with reference to specific exemplary embodiments. Various modifications and changes, however, may be made without departing from the scope of the present technology. The description and figures are to be regarded in an illustrative manner, rather than a restrictive one and all such modifications are intended to be included within the scope of the present technology. Accordingly, the scope of the technology should be determined by the generic embodiments described and their legal equivalents rather than by merely the specific examples described above. For example, the steps recited in any method or process embodiment may be executed in any order, unless otherwise expressly specified, and are not limited to the explicit order presented in the specific examples. Additionally, the components and/or elements recited in any apparatus embodiment may be assembled or otherwise operationally configured in a variety of permutations to produce substantially the same result as the present technology and are accordingly not limited to the specific configuration recited in the specific examples.

Benefits, other advantages and solutions to problems have been described above with regard to particular embodiments. Any benefit, advantage, solution to problems or any element that may cause any particular benefit, advantage or solution to occur or to become more pronounced, however, is not to be construed as a critical, required or essential feature or component.

The terms “comprises”, “comprising”, or any variation thereof, are intended to reference a non-exclusive inclusion, such that a process, method, article, composition or apparatus that comprises a list of elements does not include only those elements recited, but may also include other elements not expressly listed or inherent to such process, method, article, composition or apparatus. Other combinations and/or modifications of the above-described structures, arrangements, applications, proportions, elements, materials or components used in the practice of the present technology, in addition to those not specifically recited, may be varied or otherwise particularly adapted to specific environments, manufacturing specifications, design parameters or other operating requirements without departing from the general principles of the same.

The present technology has been described above with reference to an exemplary embodiment. However, changes and modifications may be made to the exemplary embodiment without departing from the scope of the present technology. These and other changes or modifications are intended to be included within the scope of the present technology, as expressed in the following claims.

1. A system, comprising:
a reactor comprising an inlet and an outlet;
a first vessel comprising a first inlet and a first outlet coupled to the inlet of the reactor;
a second vessel comprising a second inlet and a second outlet coupled to the inlet of the reactor; and
an exhaust system coupled to the outlet of the reactor, the first inlet of the first vessel, and the second inlet of the second vessel;
wherein one of the first vessel and the second vessel is configured to sublimate a solid precursor therein for processing, and wherein the other of the first vessel and the second vessel is maintained in an idle state having a temperature that allows unused precursor received from the exhaust system to recondense therein.

2. The system of claim 1, wherein the exhaust system comprises a feedback portion that couples the reactor to the first vessel and the second vessel.

3. The system of claim 2, wherein the feedback portion comprises a junction comprising a first leg coupled to the first vessel and a second leg coupled to the second vessel.

4. The system of claim 3, wherein a first valve is coupled to the first leg to regulate flow to the first vessel, and a second valve is coupled to the second leg to regulate flow to the second vessel.

5. The system of claim 3, wherein the feedback portion comprises a filter.

6. The system of claim 5, wherein the filter is disposed upstream of the junction.

7. The system of claim 1, wherein each of the first vessel and the second vessel comprises a heating device and a cooling device.

8. A method, comprising:
flowing a precursor from a first vessel to a reactor for processing;
flowing unused precursor from the reactor into an exhaust system coupled to the reactor;
flowing the unused precursor from the exhaust system to a second vessel; and
condensing the unused precursor into a solid state in the second vessel to be used as the precursor in future processing.

9. The method of claim 8, further comprising flowing the unused precursor from the reactor into a feedback portion of the exhaust system, wherein the feedback portion of the exhaust system is coupled between the reactor and the second vessel.

10. The method of claim 8, wherein the first vessel is in a processing state configured to sublimate a solid precursor into the precursor, and the second vessel is in an idle state at a temperature that allows the precursor to remain in the solid state.

11. The method of claim 10, further comprising monitoring a precursor level in the first vessel.

12. The method of claim 11, further comprising, in response to the precursor level in the first vessel being below a predetermined minimum threshold, changing the first vessel from the processing state to the idle state, and changing the second vessel from the idle state to the processing state.

13. The method of claim 12, further comprising flowing the precursor from the second vessel to the reactor for processing.

14. The method of claim 13, further comprising flowing the unused precursor from the reactor into the exhaust system, and into the first vessel.

15. The method of claim 14, further comprising condensing the unused precursor into the solid state in the first vessel to be used as the precursor in future processing.

16. The method of claim 8, further comprising flowing the unused precursor through a filter during the flowing the unused precursor to the second vessel.

17. The method of claim 8, wherein the flowing unused precursor from the reactor and into the exhaust system comprises purging the reactor with an inert gas.

18. A method, comprising:
flowing a precursor from a first vessel to a reactor for processing;
flowing unused precursor from the reactor to a second vessel; and
condensing the unused precursor into a solid state in the second vessel to be used as the precursor in future processing.

19. The method of claim 18, wherein the first vessel is in a processing state configured to sublimate a solid precursor into the precursor, and the second vessel is in an idle state at a temperature that allows the precursor to remain in the solid state.

20. The method of claim 19, further comprising:
monitoring a precursor level in the first vessel;
in response to the precursor level in the first vessel being below a predetermined minimum threshold, changing the first vessel from the processing state to the idle state, and changing the second vessel from the idle state to the processing state;
flowing the precursor from the second vessel to the reactor for processing; and
flowing the unused precursor from the reactor to the first vessel.
